(19) United States
(12) Patent Application Publication
(10) Pub. No.: US 2026/0059889 A1
(43) Pub. Date: Feb. 26, 2026

(54) PHOTOELECTRIC PACKAGING STRUCTURE AND CAMERA MODULE

(71) Applicant: TRIPLE WIN TECHNOLOGY (SHENZHEN) CO. LTD., Shenzhen (CN)

(72) Inventors: HSIN-YEN HSU, New Taipei (TW); TZU-LI FENG, New Taipei (TW); HUNG-TA LI, New Taipei (TW); YI-MOU HUANG, New Taipei (TW)

(21) Appl. No.: 19/249,038

(22) Filed: Jun. 25, 2025

(30) Foreign Application Priority Data
Aug. 22, 2024 (CN) 202411159134.8

(51) Int. Cl. H10F 39/00

(52) U.S. Cl. CPC H10F 39/811; H10F 39/804

(57) ABSTRACT

A photoelectric packaging structure and camera module are provided. The structure includes a substrate module, a photosensitive chip, and a plastic packaging module. The substrate module includes a dielectric layer and a first multilayered wiring structure located in the dielectric layer. The first multilayered wiring structure includes a first wiring layer and a second wiring layer, the first wiring layer has a first conductive pad and a first conductive portion, the second wiring layer has a second conductive pad and a second conductive portion, the first and the second conductive portion are electrically connected to each other to form a first conductive channel. A non-photosensitive area of the photosensitive chip has a connection pad connected to the second conductive portion, such that the photosensitive chip is electrically connected to the first wiring layer through the first conductive channel. The plastic packaging module covers the photosensitive chip.

### CROSS-REFERENCE TO RELATED APPLICATION

This application claims the benefit and priority to Chinese Patent Application Serial No. 202411159134.8, filed on Aug. 22, 2024, entitled “PHOTOELECTRIC PACKAGING STRUCTURE AND CAMERA MODULE”, and the content of which is hereby fully incorporated by reference.

### FIELD

The subject matter herein generally relates to semiconductor packages, and more particularly, to a photoelectric packaging structure and a camera module with the photoelectric packaging structure.

### BACKGROUND

Camera modules may include circuit boards and photosensitive chips mounted on the circuit boards. The photosensitive chip may be connected to conductive pads of the circuit board through a wire bonding technology or a flip-chip packaging technology.

However, a wire bonding tool needs a certain space between the photosensitive chip and the conductive pad of the circuit board when operated, which results in an increase in the lateral size between the photosensitive chip and the conductive pad. Furthermore, the flip-chip packaging requires the circuit board to have high flatness and symmetrically distributed solder pads, resulting in low universality. Improvements in the art are desired.

### BRIEF DESCRIPTION OF THE DRAWINGS

FIG. 1 is a block diagram of a camera module according to an embodiment of the present disclosure.

FIG. 2 is a diagrammatic view of a photoelectric packaging structure of the camera module shown in FIG. 1.

FIG. 3 is a diagrammatic view of a photoelectric packaging structure according to another embodiment of the present disclosure.

FIG. 4 is a diagrammatic view of a photoelectric packaging structure according to yet another embodiment of the present disclosure.

FIG. 5 is a diagrammatic view of a photoelectric packaging structure according to yet another embodiment of the present disclosure.

FIG. 6 is a diagrammatic view of a photoelectric packaging structure according to yet another embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Implementations of the present disclosure will now be described, by way of embodiments, with reference to the above figures. The embodiments are obviously a portion but not all of the embodiments of the present disclosure.

When a component is fixed to another component, the two components may be directly fixed to each other or indirectly fixed to each other or through an intermediate medium. When a component is located on another component, the component may be directly located on the another component, or an intermediate medium may exist therebetween.

Unless otherwise defined, the technical terms used in the present disclosure have the same meanings as those commonly understood by those skilled in the art. The terms used in the present disclosure are for describing specific embodiments but not intended to limit the scope of present disclosure.

### First Embodiment

Referring to FIG. 1, a camera module 1 is provided according to an embodiment of the present disclosure. The camera module 1 includes a lens assembly 2 and a photoelectric packaging structure 100. The lens assembly 2 has an optical path for an external light beam to pass through. The photoelectric packaging structure 100 receives the external light beam passing through the lens assembly 2 to form an optical signal, and then converts the optical signal into electrical signal to realize photoelectric conversion.

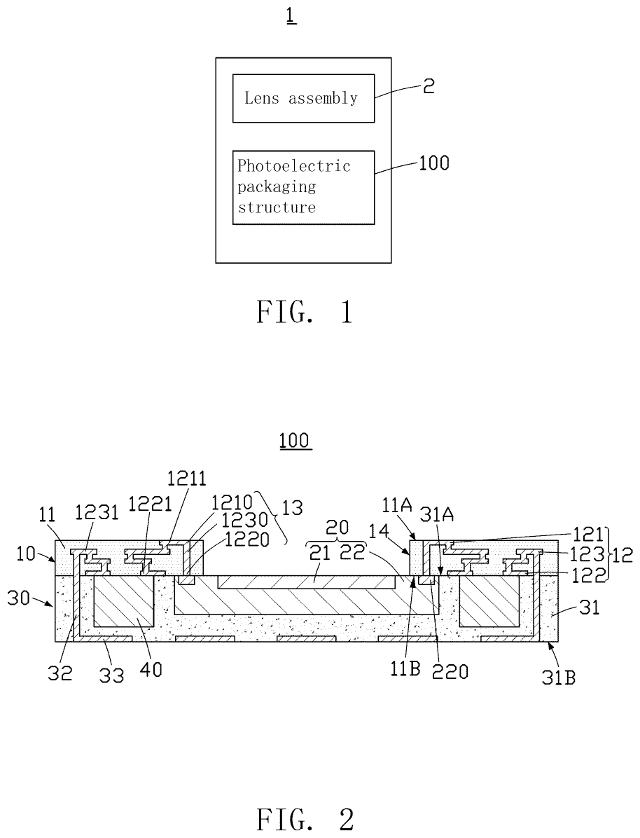

Referring to FIG. 2, the photoelectric packaging structure 100 includes a substrate module 10, a photosensitive chip 20, and a plastic packaging module 30. The substrate module 10 includes a dielectric layer 11 and a first multilayered wiring structure 12. The dielectric layer 11 includes a first surface 11A and a second surface 11B opposite to each other. The lens assembly 2 may be located on the first surface 11A. The first multilayered wiring structure 12 is formed in the dielectric layer 11 and includes a first wiring layer 121, a second wiring layer 122, and a third wiring layer 123. The first wiring layer 121, the second wiring layer 122, and the third wiring layer 123 are stacked with each other along a thickness direction of the substrate module 10. The first wiring layer 121, the second wiring layer 122, and the third wiring layer 123 are electrically connected to each other. The first wiring layer 121 and the second wiring layer 122 may be the outermost wiring layers, and at least one third wiring layer 123 may be located between the first wiring layer 121 and the second wiring layer 122. That is, the first multilayered wiring structure 12 may include at least three wiring layers. It can be understood that in other embodiments, the first multilayered wiring structure 12 may also include two wiring layers stacked along the thickness direction of the substrate module 10. The first wiring layer 121 includes a first conductive pad 1211 and a first conductive portion 1210. The first conductive pad 1211 and a first conductive portion 1210 are connected to each other. The first conductive pad 1211 and a first conductive portion 1210 may be exposed from the first surface 11A.

The second wiring layer 122 includes a second conductive pad 1221 and a second conductive portion 1220. The second conductive pad 1221 and the second conductive portion 1220 are exposed from the second surface 11B. The first conductive portion 1210 and the second conductive portion 1220 are electrically connected to each other along the thickness direction of the substrate module 10 to form a first conductive channel 13. The first conductive channel 13 is located in the dielectric layer 11 and extends through the first surface 11A and the second surface 11B. The first conductive channel 13 may extend along the thickness direction of the substrate module 10. The substrate module 10 may further include a through hole 14 formed in the dielectric layer 11. The through hole 14 extends through the first surface 11A and the second surface 11B, and the through hole 14 is spaced from the first multilayered wiring structure 12. In some embodiments, each of the first multilayered wiring structure 12 and the first conductive channel 13 includes a conductive material. The conductive material may be a conductive ink or a metal material. The conductive ink may include an element selected from a group consisting of silver, platinum, gold, copper, nickel, aluminum, and any combination thereof. The metal material may be silver, copper, or gold. The various conductive portion of the first conductive channel 13 (i.e., the first conductive portion 1210, the second conductive portion 1220, and the third conductive portion 1230) may be formed by defining a hollow channel in the dielectric layer 11 and filling the conductive material in the hollow channel. In some embodiments, the dielectric layer 11 may include a resin selected from a group consisting of epoxy resin, polyphenylene ether, polyimide, polyethylene terephthalate, and polyethylene naphthalate.

The photosensitive chip 20 is located on the second surface 11B. The photosensitive chip 20 includes a photosensitive area 21 and a non-photosensitive area 22 connected to each other. The photosensitive area 21 corresponds to the through hole 14. The photosensitive area 21 receives the optical signal formed by the external light beam passing through the lens assembly 2, and then converts the optical signal into the electrical signal. The non-photosensitive area 22 may surround the photosensitive area 21. A connection pad 220 (such as an aluminum pad) may be provided on the non-photosensitive area 22. The connection pad 220 faces the second surface 11B. The second conductive portion 1220 is connected to the connection pad 220, such that the photosensitive chip 20 is electrically connected to the first wiring layer 121 through the first conductive channel 13. Through the Redistribution Layer (RDL) process, the first conductive pad 1211 redistributes the connection pad 220 of the non-photosensitive area 22, to transmit the electrical signal of the photosensitive chip 20 to an external component (such as a system terminal, a circuit board, or a chip) through the first multilayered wiring structure 12. The specific position of the first conductive pad 1211 in the dielectric layer 11 may be adjusted.

The plastic packaging module 30 is located on the second surface 11B. The plastic packaging module 30 includes a packaging body 31. The packaging body 31 covers at least a sidewall of the photosensitive chip 20. The packaging body 31 improves the stability of the photosensitive chip 20. The packaging body 31 includes a third surface 31A facing the second surface 11B and a fourth surface 31B opposite to the third surface 31A. In some embodiments, the fourth surface 31B may be located below the photosensitive chip 20, that is, the packaging body 31 may also cover the bottom surface of the photosensitive chip 20. In some embodiments, the packaging body 31 includes at least one of an epoxy resin and a phenolic resin.

In the photoelectric packaging structure 100 of the present disclosure, the connection pad 220 is in direct contact with the second conductive portion 1220 of the second wiring layer 122, and electrically connected to the first wiring layer 121 through the first conductive channel 13. That is, the connection pad 220 is in direct contact with the first conductive channel 13, and an additional connection medium is not needed between the connection pad 220 and the first conductive channel 13. Compared to the existing wire bonding process, the signal conduction path in the first conductive channel 13 is shorter, which is beneficial for improving the quality of signal transmission. Furthermore, there is no need to reserve the space required for wire bonding tool, which is beneficial for reducing the lateral size of the photoelectric packaging structure 100 and conducive to the miniaturization of the photoelectric packaging structure 100. Meanwhile, compared to the existing flip-chip packaging process, the present disclosure is not limited to using a photosensitive chip with symmetrically distributed solder pads, and is also not limited by the size of metal balls that results in excessively high requirements for the flatness of the substrate. In addition, since the lens assembly 2 is located on the first surface 11A, the lens assembly 2 also protects the photosensitive area 21 of the photosensitive chip 20, thereby reducing the damages to the photosensitive area 21 under an external force. Since the first surface 11A has a high flatness, it is also conducive to installing the lens assembly 2 on the first surface 11A and increasing the connecting area between the lens assembly 2 and the substrate module 10, thereby improving the connecting strength between the lens assembly 2 and the substrate module 10.

In some embodiments, the connection pad 220 and the first multilayered wiring structure 12 are made of a same conductive material. For example, each of the connection pad 220 and the first multilayered wiring structure 12 is made of silver. Due to the use of the same conductive material, it is beneficial to further improve the quality of signal transmission.

In some embodiments, the third wiring layer 122 includes a third conductive pad 1231 and a third conductive portion 1230. Two sides of the third conductive portion 1230 are connected to the first conductive portion 1210 and the second conductive portion 1220, respectively. The first conductive portion 1210, the second conductive portion 1220, and the third conductive portion 1230 cooperatively constitute the first conductive channel 13. The plastic packaging module 30 further includes a second conductive channel 32 and a first solder pad 33. The second conductive channel 32 is formed in the packaging body 31 and a portion of the dielectric layer 11. The second conductive channel 32 extends through the third surface 31A and the fourth surface 31B of the packaging body 31. The first solder pad 33 is exposed from the fourth surface 31B. Two ends of the second conductive channel 32 are connected to the third conductive pad 1231 and the first solder pad 33, respectively. By exposing the first solder pad 33 from the fourth surface 31B, it facilitates the connection between the first solder pad 33 and the external component. As such, the electrical signal generated by the photosensitive chip 20 may be transmitted to the external components sequentially through the first conductive channel 13, the first multilayered wiring structure 12, the second conductive channel 32, and the first solder pad 33. That is, the first conductive channel 13 and the second conductive channel 32 cooperate with each other to deliver the electrical signal out of the fourth surface 31B. In some embodiments, each of the second conductive channel 32 and the first solder pad 33 includes a conductive material, and the conductive material may include a conductive ink or a metal material. The conductive ink may include an element from a group consisting of silver, platinum, gold, copper, nickel, aluminum, and any combination thereof. The metal material may be silver, copper, or gold. In some embodiments, the connection pad 220, the first multilayered wiring structure 12, the second conductive channel 32, and the first solder pad 33 are made of the same conductive material, thereby further improving the quality of signal transmission.

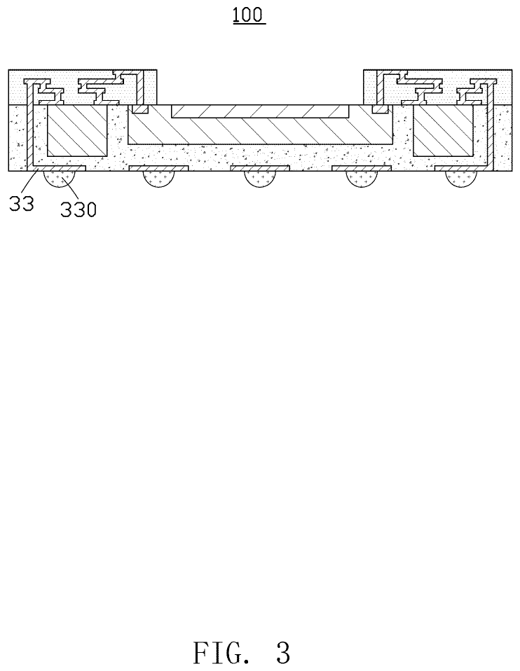

Referring to FIG. 3, in some embodiments, a solder ball 330 may also be provided on the first solder pad 33. The above external component may be installed on the solder ball 330, such that the electrical signal transmitted to the first solder pad 33 may further be transmitted to the external component through the solder ball 330. The solder ball 330 may be a tin ball.

As shown in FIG. 2, the photoelectric packaging structure 100 may further include a first electronic component 40 connected to the second conductive pad 1221. The packaging body 31 also covers the first electronic component 40. Through the RDL process, the first conductive pad 1211 redistributes the connection pad 220 of the non-photosensitive area 22 to transmit the electrical signal of the photosensitive chip 20 to the first electronic component 40, and then transmits the electrical signal from the first electronic component 40 to the external component. The first electronic component 40 may be a passive component or an active component. The passive component includes a resistor, a capacitor, etc. The active component includes a transistor, an integrated circuit, a picture tube, etc. In the embodiment, the first electronic component 40 is an active component.

### Second Embodiment

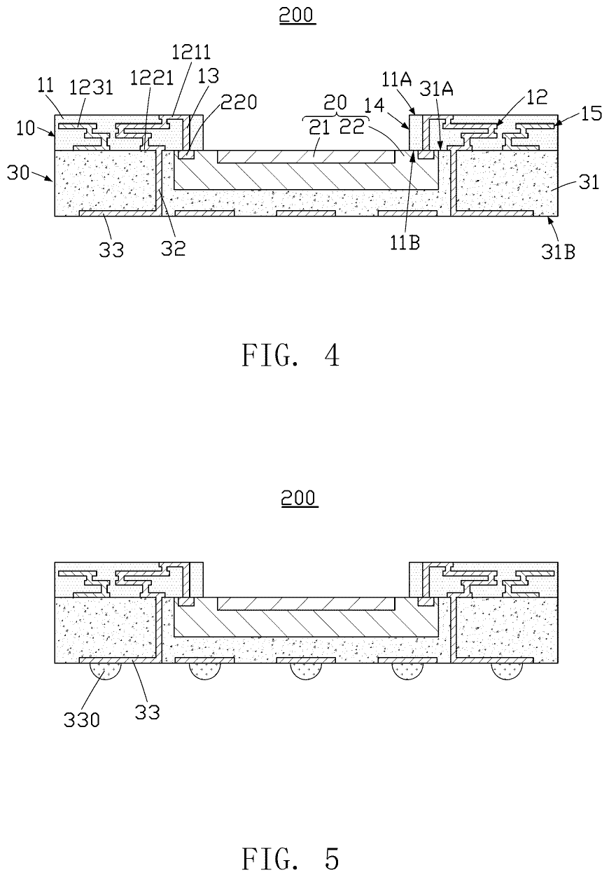

Referring to FIG. 4, a photoelectric packaging structure 200 is provided according to another embodiment of the present disclosure. The difference from the above photoelectric packaging structure 100 includes the position of the second conductive channel 32. Specifically, the second conductive channel 32 is located in the packaging body 31 and extends through the third surface 31A and the fourth surface 31B. The second conductive channel 32 does not extend into the dielectric layer 11. The first solder pad 33 is exposed from the fourth surface 31B. The two ends of the second conductive channel 32 are connected to the second conductive pad 1221 and the first solder pad 33, respectively.

As shown in FIG. 5, in some embodiments, a solder ball 330 may also be provided on the first solder pad 33. The solder ball 330 may be a tin ball.

In some embodiments, the substrate module 10 may further include a second multilayered wiring structure 15 formed in the dielectric layer 11. The second multilayered wiring structure 15 is electrically connected to the first multilayered wiring structure 12. The second multilayered wiring structure 15 constitutes a second electronic component. The second electronic component may be an active component or a passive component. The active component includes a transistor, an integrated circuit, or an image tube. The passive component includes a resistor, an inductor, a capacitor, etc. In the embodiment, the second electronic component is a passive component. In some embodiments, each of the second multilayered wiring structure 15, the first multilayered wiring structure 12, and the first conductive channel 13 includes a conductive material, and the conductive material may be a conductive ink or a metal material. The conductive ink may include an element selected from a group consisting of silver, platinum, gold, copper, nickel, aluminum, and any combination thereof. The metal material may be silver, copper, or gold.

### Third embodiment

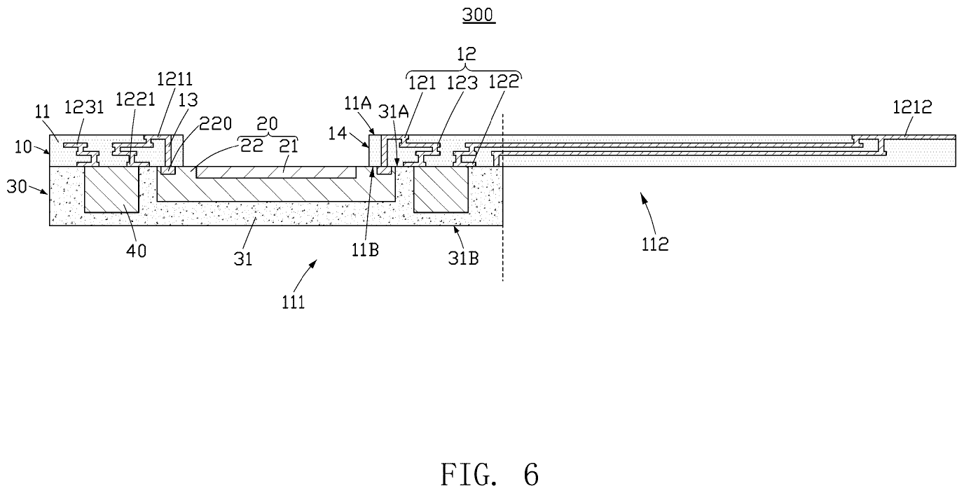

Referring to FIG. 6, a photoelectric packaging structure 300 is provided according to yet another embodiment of the present disclosure. The difference from the above photoelectric packaging structure 100 includes the structure of the substrate module 10. Specifically, the substrate module 10 includes a first substrate region 111 and a second substrate region 112 connected to each other. Along the thickness direction of the substrate module 10, the first substrate region 111 overlaps with the plastic packaging module 30, and the second substrate region 112 extends beyond the plastic packaging module 30, which indicates that a width of the substrate module 10 is greater than that of the plastic packaging module 30. The first wiring layer 121 further includes a second solder pad 1212. The first conductive pad 1211 and the second solder pad 1212 of the first wiring layer 121 are located at the first substrate region 111 and the second substrate region 112, respectively. The second solder pad 1212 is exposed from the first surface 11A, which facilitates the connection of the external component on the second solder pad 1212. At this time, the electrical signal generated by the photosensitive chip 20 may be delivered out of the first surface 11A.

The first multilayered wiring structure 12 is located in the first substrate region 111 and extends to the second substrate region 112. When the first multilayered wiring structure 12 includes the first wiring layer 121, at least one third wiring layer 123, and the second wiring layer 122, each of the first wiring layer 121 or the third wiring layer 123 is partially located in the first substrate region 111 and partially located in the second substrate region 112. The second wiring layer 122 is only located in the first substrate region 111. The first wiring layer 121 located in the first substrate region 111 may be fabricated simultaneously with the first wiring layer 121 located in the second substrate region 112. The third wiring layer 123 located in the first substrate region 111 may be fabricated simultaneously with the third wiring layer 123 located in the second substrate region 112..

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A photoelectric packaging structure comprising:
a substrate module comprising a dielectric layer and a first multilayered wiring structure located in the dielectric layer, wherein the dielectric layer comprises a first surface and a second surface opposite to each other, the first multilayered wiring structure comprises a first wiring layer and a second wiring layer stacked with each other in a thickness direction of the substrate module, the first wiring layer comprises a first conductive pad and a first conductive portion connected to each other, the second wiring layer comprises a second conductive pad and a second conductive portion, the second conductive pad and the second conductive portion are exposed from the second surface, the first conductive portion and the second conductive portion are electrically connected to each other in the thickness direction to form a first conductive channel;
a photosensitive chip located on the second surface, and comprising a photosensitive area and a non-photosensitive area connected to each other, wherein the non-photosensitive area comprises a connection pad facing the second surface, the second conductive portion is connected to the connection pad, such that the photosensitive chip is electrically connected to the first wiring layer through the first conductive channel; and
a plastic packaging module located on the second surface and covering the photosensitive chip.

2. The photoelectric packaging structure according to claim 1, wherein the first multilayered wiring structure further comprises a third wiring layer located between the first wiring layer and the second wiring layer, the third wiring layer comprises a third conductive pad and a third conductive portion, two sides of the third conductive portion are electrically connected to the first conductive portion and the second conductive portion, respectively, to cooperatively constitute the first conductive channel;
the plastic packaging module comprises a packaging body, a second conductive channel, and a first solder pad, the packaging body covers the photosensitive chip, the packaging body comprises a third surface facing the second surface and a fourth surface opposite to the third surface, the second conductive channel is located in the packaging body and a portion of the dielectric layer, the second conductive channel extends through the third surface and the fourth surface, the first solder pad is exposed from the fourth surface and configured to connect to an external component, two ends of the second conductive channel are connected to the third conductive pad and the first solder pad, respectively.

3. The photoelectric packaging structure according to claim 2, further comprising a first electronic component, wherein the packaging body further covers the first electronic component, and the first electronic component is connected to the second conductive pad.

4. The photoelectric packaging structure according to claim 1, wherein the plastic packaging module comprises a packaging body, a second conductive channel, and a first solder pad, the packaging body covers the photosensitive chip, the packaging body comprises a third surface facing the second surface and a fourth surface opposite to the third surface, the second conductive channel is formed in the packaging body and extends through the third surface and the fourth surface, the first solder pad is exposed from the fourth surface and configured to connect to an external component, and two ends of the second conductive channel are connected to the second conductive pad and the first solder pad, respectively.

5. The photoelectric packaging structure according to claim 4, wherein the substrate module further comprises a second multilayered wiring structure, the second multilayered wiring structure is located in the dielectric layer and electrically connected to the first multilayered wiring structure, and the second multilayered wiring structure forms a second electronic component.

6. The photoelectric packaging structure according to claim 2, further comprising a solder ball formed on the first solder pad.

7. The photoelectric packaging structure according to claim 2, wherein the connection pad, the first multilayered wiring structure, the second conductive channel, and the first solder pad are made of a same conductive material.

8. The photoelectric packaging structure according to claim 7, wherein the conductive material is a conductive ink or a metal material.

9. The photoelectric packaging structure according to claim 1, wherein the substrate module comprises a first substrate region and a second substrate region connected to each other, the first substrate region overlaps with the plastic packaging module, the second substrate region extends beyond the plastic packaging module, the first multilayered wiring structure is located in the first substrate region and extends to the second substrate region, the first conductive pad and the second conductive pad are located in the first substrate region, the first wiring layer further comprises a second solder pad, the second solder pad is located in the second substrate region, and the second solder pad is exposed from the first surface and configured to connect an external component.

10. The photoelectric packaging structure according to claim 1, wherein the substrate module defines a through hole, the through hole is spaced from the first multilayered wiring structure, and the photosensitive area is exposed from the through hole.

11. A camera module comprising:
a lens assembly; and
a photoelectric packaging structure comprising:
a substrate module comprising a dielectric layer and a first multilayered wiring structure located in the dielectric layer, wherein the dielectric layer comprises a first surface and a second surface opposite to each other, the first multilayered wiring structure comprises a first wiring layer and a second wiring layer stacked with each other in a thickness direction of the substrate module, the first wiring layer comprises a first conductive pad and a first conductive portion connected to each other, the second wiring layer comprises a second conductive pad and a second conductive portion, the second conductive pad and the second conductive portion are exposed from the second surface, the first conductive portion and the second conductive portion are electrically connected to each other in the thickness direction to form a first conductive channel;
a photosensitive chip located on the second surface, and comprising a photosensitive area and a non-photosensitive area connected to each other, wherein the non-photosensitive area comprises a connection pad facing the second surface, the second conductive portion is connected to the connection pad, such that the photosensitive chip is electrically connected to the first wiring layer through the first conductive channel; and
a plastic packaging module located on the second surface and covering the photosensitive chip, wherein the lens assembly is disposed on a side of the substrate module away from the plastic packaging module.

12. The camera module according to claim 11, wherein the first multilayered wiring structure further comprises a third wiring layer located between the first wiring layer and the second wiring layer, the third wiring layer comprises a third conductive pad and a third conductive portion, two sides of the third conductive portion are electrically connected to the first conductive portion and the second conductive portion, respectively, to cooperatively constitute the first conductive channel;
the plastic packaging module comprises a packaging body, a second conductive channel, and a first solder pad, the packaging body covers the photosensitive chip, the packaging body comprises a third surface facing the second surface and a fourth surface opposite to the third surface, the second conductive channel is located in the packaging body and a portion of the dielectric layer, the second conductive channel extends through the third surface and the fourth surface, the first solder pad is exposed from the fourth surface and configured to connect to an external component, two ends of the second conductive channel are connected to the third conductive pad and the first solder pad, respectively.

13. The camera module according to claim 12, wherein the photoelectric packaging structure further comprises a first electronic component, the packaging body further covers the first electronic component, and the first electronic component is connected to the second conductive pad.

14. The camera module according to claim 11, wherein the plastic packaging module comprises a packaging body, a second conductive channel, and a first solder pad, the packaging body covers the photosensitive chip, the packaging body comprises a third surface facing the second surface and a fourth surface opposite to the third surface, the second conductive channel is formed in the packaging body and extends through the third surface and the fourth surface, the first solder pad is exposed from the fourth surface and configured to connect to an external component, and two ends of the second conductive channel are connected to the second conductive pad and the first solder pad, respectively.

15. The camera module according to claim 14, wherein the substrate module further comprises a second multilayered wiring structure, the second multilayered wiring structure is located in the dielectric layer and electrically connected to the first multilayered wiring structure, and the second multilayered wiring structure forms a second electronic component.

16. The camera module according to claim 12, wherein the photoelectric packaging structure further comprises a solder ball formed on the first solder pad.

17. The camera module according to claim 12, wherein the connection pad, the first multilayered wiring structure, the second conductive channel, and the first solder pad are made of a same conductive material.

18. The camera module according to claim 17, wherein the conductive material is a conductive ink or a metal material.

19. The camera module according to claim 11, wherein the substrate module comprises a first substrate region and a second substrate region connected to each other, the first substrate region overlaps with the plastic packaging module, the second substrate region extends beyond the plastic packaging module, the first multilayered wiring structure is located in the first substrate region and extends to the second substrate region, the first conductive pad and the second conductive pad are located in the first substrate region, the first wiring layer further comprises a second solder pad, the second solder pad is located in the second substrate region, and the second solder pad is exposed from the first surface and configured to connect an external component.

20. The camera module according to claim 11, wherein the substrate module defines a through hole, the through hole is spaced from the first multilayered wiring structure, and the photosensitive area is exposed from the through hole.
